(19) United States
(12) Patent Application Publication
(10) Pub. No.: US 2025/0046721 A1
(43) Pub. Date: Feb. 6, 2025

(54) SEMICONDUCTOR PACKAGE AND MANUFACTURING METHOD FOR THE SAME

(71) Applicant: SAMSUNG ELECTRONICS CO.,LTD., Suwon-si (KR)

(72) Inventors: Choongbin YIM, Suwon-si (KR); Jongkook KIM, Suwon-si (KR); Chengtar WU, Suwon-si (KR)

(73) Assignee: SAMSUNG ELECTRONICS CO.,LTD., Suwon-si (KR)

(21) Appl. No.: 18/592,004

(22) Filed: Feb. 29, 2024

(30) Foreign Application Priority Data
Aug. 2, 2023 (KR) 10-2023-0100897

(51) Int. Cl. H01L 23/538; H01L 21/48; H01L 21/56; H01L 23/00; H01L 23/31; H01L 23/498; H01L 25/10

(52) U.S. Cl. CPC H01L 23/5383; H01L 21/4857; H01L 21/56; H01L 23/3128; H01L 23/49816; H01L 23/49827; H01L 24/08; H01L 25/105; H01L 24/16; H01L 2224/08235; H01L 2224/16227

(57) ABSTRACT

A semiconductor package includes a support substrate having a through hole and including an insulating layer, one or more wiring layers including a first wiring layer, and a first electronic device on the first wiring layer, a semiconductor chip positioned in the through hole to be at least partially surrounded by the support substrate and including a connection pad on a first surface of the semiconductor chip, an encapsulant filling at least a portion of the through hole and encapsulating at least a portion of the semiconductor chip, a first redistribution layer structure on the first surface of the semiconductor chip and including a first redistribution layer, and a second redistribution layer structure over a second surface of the semiconductor chip that is opposite to the first surface of the semiconductor chip, the second redistribution layer structure including a second redistribution layer.

### CROSS-REFERENCE TO RELATED APPLICATION

This application is based on claims priority to Korean Patent Application No. 10-2023-0100897, filed on Aug. 2, 2023, in the Korean Intellectual Property Office, the disclosure of which is incorporated by reference herein in its entirety.

### BACKGROUND

### 1. Field

The present disclosure relates to a semiconductor device and a fabricating method thereof.

### 2. Description of Related Art

In semiconductor package technology, an electronic element such as a capacitor that is electrically connected to a semiconductor chip may be mounted on a semiconductor package to improve performance, such as a power characteristic of the semiconductor chip.

For example, in a ball grid array (BGA) package structure, an electronic device may be mounted on a lower side of the package with solder balls using surface mount technology (SMT). In this case, a number of electronic devices that can be mounted on the semiconductor package may be limited due to an area, a number, etc., occupied by the solder balls.

In addition, in a package on package (POP) structure in which other semiconductor packages are stacked on a semiconductor package, an electronic device may need to be electrically connected to the semiconductor chip of the upper package. In this case, the electronic device may be positioned such that the electronic device has a short electrical connection path with the semiconductor chip of the upper package. Therefore, a semiconductor package structure is needed that can position additional electronic devices having a short electrical connection path with the semiconductor chip in addition to electronic devices mounted on a lower side of the upper semiconductor package.

### SUMMARY

Example embodiments provide a semiconductor package capable of overcoming limitations of space constraints for disposition of electronic devices, and a manufacturing method of the semiconductor package.

Further, example embodiments provide a semiconductor package having a short electrical connection path with a semiconductor chip, and a manufacturing method of the semiconductor package.

Further still, example embodiments provide a semiconductor package with improved performance, and a manufacturing method of the semiconductor package.

Additional aspects will be set forth in part in the description which follows and, in part, will be apparent from the description, or may be learned by practice of the presented embodiments.

According to an aspect of an example embodiment, a semiconductor package may include a support substrate having a through hole extending from a first side of the support substrate to a second side of the support substrate opposite to the first side of the support substrate and including an insulating layer, one or more wiring layers including a first wiring layer, and a first electronic device on the first wiring layer, a semiconductor chip positioned in the through hole to be at least partially surrounded by the support substrate and including a connection pad on a first surface of the semiconductor chip, an encapsulant filling at least a portion of the through hole and encapsulating at least a portion of the semiconductor chip, a first redistribution layer structure on the first surface of the semiconductor chip and including a first redistribution layer, and a second redistribution layer structure over a second surface of the semiconductor chip that is opposite to the first surface of the semiconductor chip, the second redistribution layer structure including a second redistribution layer, where the first wiring layer is between the first electronic device and the second redistribution layer structure and the insulating layer integrally covers the first wiring layer, a side surface of the first electronic device, and a surface of the first electronic device opposite to a surface of the first electronic device facing the first wiring layer.

According to an aspect of an example embodiment, a semiconductor package may include a first semiconductor package and a second semiconductor package on the first semiconductor package, where the first semiconductor package includes a support substrate including one or more wiring layers including a first wiring layer, a first electronic device on the first wiring layer, and an insulating layer at least partially covering the first wiring layer and the first electronic device, a first semiconductor chip, an encapsulant encapsulating at least a portion of the first semiconductor chip, a first redistribution layer structure including a first redistribution layer on a first surface of the first semiconductor chip, the first redistribution layer being connected to the first semiconductor chip and the one or more wiring layers, and a second redistribution layer structure including a second redistribution layer over a second surface of the first semiconductor chip opposite to the first surface of the first semiconductor chip, the second redistribution layer being connected to the one or more wiring layers, and where the second semiconductor package includes a second semiconductor chip connected to the first electronic device.

According to an aspect of an example embodiment, a method of manufacturing a semiconductor package may include preparing a support substrate, forming a through hole in the support substrate, providing a semiconductor chip in the through hole, encapsulating the semiconductor chip, forming a first redistribution layer structure on a first surface of the semiconductor chip, the first redistribution layer structure including a first redistribution layer, and forming a second redistribution layer structure over a second surface of the semiconductor chip opposite to the first surface of the semiconductor chip, the second redistribution layer structure including a second redistribution layer, where the preparing of the support substrate includes forming a wiring layer, providing an electronic device on the wiring layer and forming an insulating layer to at least partially cover the wiring layer and the electronic device.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more example embodiments;

FIG. 2 is a bottom view of the semiconductor package of in FIG. 1 according to one or more example embodiments;

FIG. 3 is a cross-sectional view illustrating a semiconductor package according to one or more example embodiments;

FIG. 4 is a cross-sectional view illustrating a semiconductor package according to one or more example embodiments;

FIG. 5 is a cross-sectional view illustrating a semiconductor package according to one or more example embodiments;

FIG. 6 is a cross-sectional view illustrating a semiconductor package having a structure in which other semiconductor packages are stacked thereon, according to one or more example embodiments; and

FIGS. 7A to 7J are diagrams illustrating a manufacturing process of a semiconductor package according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Further, since sizes and thicknesses of constituent members shown in the accompanying drawings may be arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, unless explicitly described to the contrary, the word “comprise” and variations such as “comprises” or “comprising” will be understood to imply the inclusion of stated elements but not the exclusion of any other elements.

Further, the phrase “in a plan view” means when an object portion is viewed from above, and the phrase “in a cross-sectional view” means when a cross-section taken by vertically cutting an object portion is viewed from the side.

In addition, sequence numbers such as 1st, 2nd, etc. are used to distinguish a certain component from other components that are the same or similar thereto, and are not necessarily intended to refer to a specific component. Accordingly, a component referred to as a first component may be referred to as a second component.

In addition, singular references to certain elements include references to a plurality of these elements, unless specifically stated to the contrary. For example, “wiring layer” may be used to indicate not only one wiring layer but also a plurality of wiring layers, such as two, three, or more.

Additionally, references to a first side and a second side are intended to distinguish different sides from each other, and are not necessarily intended to limit it to a specific side. Accordingly, a side referred to as a first side may also be referred to as a second side.

Hereinafter, a semiconductor package according to embodiments of the present disclosure will be described with reference to the drawings.

In this specification, upper and lower sides are described as respectively referring to upper and lower sides in a direction from a first redistribution layer structure 140 to a second redistribution layer structure 150. In addition, upper and lower sides are described as indicating one side to an upper side and one side to a lower side, respectively. Furthermore, in some instances, individual components may be referred to with respect to their position/correspondence as shown in the figures, while utilizing the same or similar reference numbers.

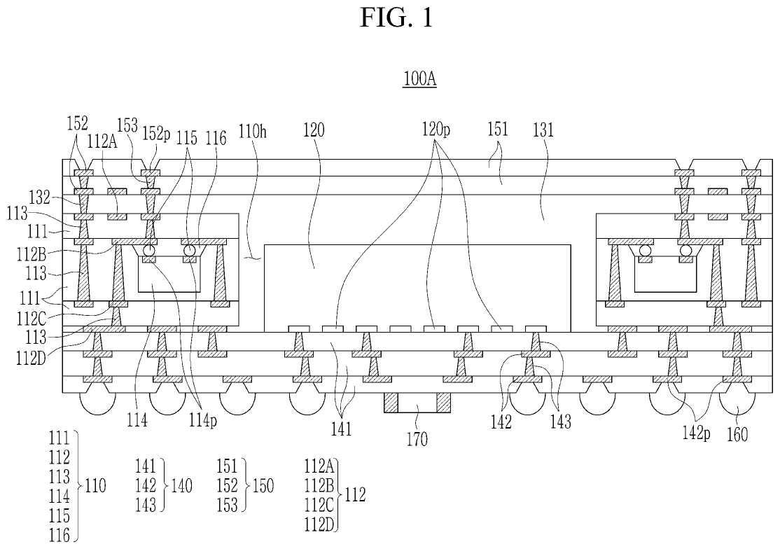

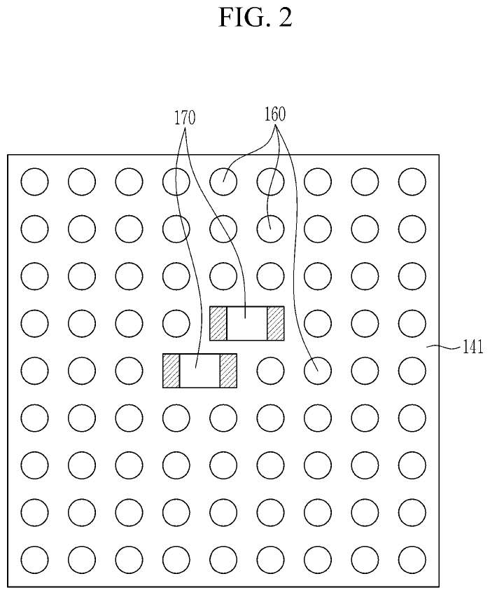

FIG. 1 is a cross-sectional view illustrating a semiconductor package according to one or more example embodiments. FIG. 2 is a bottom view of the semiconductor package of in FIG. 1 according to one or more example embodiments.

Referring to FIGS. 1 and 2, the semiconductor package 100A may include a support substrate 110, a semiconductor chip 120, an encapsulant 131, a first redistribution layer structure 140, a second redistribution layer structure 150, a connection structure 160 and an electronic device 170.

The support substrate 110 may include an insulating layer 111, a wiring layer 112, a via 113, an electronic device 114, a conductive bump 115 and an underfill 116. Additionally, the support substrate 110 may have a through hole 110h. As shown in FIG. 1, the support substrate 110 may include a plurality of insulating layers 111, a plurality of wiring layers 112, a plurality of vias 113, and a plurality of conductive bumps 115.

The through hole 110h may extend through the support substrate 110 in a thickness direction from a first side of the support substrate 110 to a second side of the support substrate 110 opposite to the first side of the support substrate 110. A method of forming the through hole 110h is not particularly limited, and may be formed, for example, by laser drilling, mechanical drilling, sand blasting, etc. According to a method of forming the through hole 110h, a width of the through hole 110h may be substantially constant in the direction from the first side of the support substrate 110 to the second side, or may be tapered. The width may refer to a distance between a first wall of the through hole 110h and a second wall facing the first wall.

The insulating layer 111 may cover or at least partially cover the wiring layer 112 and the electronic device 114. As described later, the insulating layer 111 may integrally cover or at least partially cover the wiring layer 112, a side of the electronic device 114, and a side of the electronic device 114 opposite to a side facing the wiring layer 112. Herein, ‘integrally’ cover may indicate covering each component at once, without boundaries among the areas covering each component. That is, the insulating layer 111 may integrally cover or at least partially cover multiple sides of the electronic device 114.

The insulating layer 111 may include an insulating material, such as a thermosetting resin such as an epoxy resin, a thermoplastic resin such as polyimide, prepreg, Ajinomoto build-up film (ABF), etc.

The insulating layer 111 may include a plurality of insulating layers 111. A number of the insulating layers 111 is not limited, and may be changed according to a design thereof. Materials of the insulating layers 111 may be the same or different from each other. When the materials of the insulating layers 111 are the same, a boundary between the insulating layers 111 may not be clear. Additionally, thicknesses of the insulating layers 111 may be the same or different. For example, among the insulating layers 111, the insulating layer 111 positioned in the middle may be thicker than the other insulating layers 111.

The wiring layer 112 may be configured to electrically connect the first redistribution layer structure 140 and the second redistribution layer structure 150.

The wiring layer 112 may include a plurality of wiring layers 112, such as a first wiring layer 112A, a second wiring layer 112B, a third wiring layer 112C and a fourth wiring layer 112D. A number of the wiring layers 112 is also not limited, and may be changed according to a design thereof. The wiring layers 112 may be disposed on the respective insulating layers 111 to be covered or at least partially covered by an insulating layer 111 disposed on another layer, and may include an exposed portion. For example, the wiring layers 112 may be disposed on lower sides of the respective insulating layers 111 to be covered or at least partially covered by an insulating layer 111 disposed on another layer, and may be exposed at an upper side of the insulating layer 111 at least partially covering the wiring layer 112. For example, the wiring layer 112D may be disposed on the lowermost insulating layer 111, and the wiring layer 112C may be at least partially covered by the lowermost insulating layer 111 on which the wiring layer 112D is disposed. The wiring layer 112D, which is the lowermost among the wiring layers 112, may contact the first redistribution layer structure 140, and may be surrounded by the encapsulant 131.

The wiring layers 112 may include a second wiring layer 112B on which the electronic device 114 is positioned, and a third wiring layer 112C positioned on the insulating layer 111 covering or at least partially covering the second wiring layer 112B and the electronic device 114. Among the wiring layers 112, the wiring layer 112 where the electronic devices 114 are positioned (e.g., wiring layer 112B) may be changed according to a design thereof.

The wiring layer 112 may include a conductive material, such as aluminum (Al), copper (Cu), gold (Au), silver (Ag), platinum (Pt), tin (Sn), chromium (Cr), palladium (Pd), lead (Pb), titanium (Ti), or an alloy thereof.

The wiring layer 112 may be formed by forming a seed layer through electroless plating, and forming a metal layer on the seed layer through electrolytic plating, but the present disclosure is not limited thereto.

A plurality of vias 113 may extend through the insulating layer 111, and may serve to connect the wiring layers 112 disposed in different layers.

A material of the wiring layer 112 may be the same as a material of the vias 113, such as aluminum (Al), copper (Cu), gold (Au), silver (Ag), platinum (Pt), tin (Sn), chromium (Cr), palladium (Pd), lead (Pb), titanium (Ti), or an alloy thereof.

The plurality of vias 113 may be formed by forming a via hole in the insulating layer 111 using methods such as laser drilling or photo lithography, disposing a seed layer on a wall side of the via hole by electroless plating, and filling the via hole with electrolytic plating, but the present disclosure is not limited thereto. The plurality of vias 113 may be formed integrally with the wiring layer 112 such that there is no boundary therebetween. When forming the seed layer on the wall side of the via hole, the plurality of vias 113 and the wiring layer 112 may be integrally formed by extending the seed layer on a first side of the insulating layer 111 and performing electrolytic plating.

The plurality of vias 113 may have various shapes, such as a tapered shape or a cylindrical shape in which a diameter thereof narrows in a direction from a first side to a second side according to a formation method. For example, the plurality of vias 113 may have a tapered shape whose width narrows upward.

The plurality of vias 113 may include a via connecting the above-described second wiring layer 112B and the third wiring layer 112C. The via connecting the second wiring layer 112B and the third wiring layer 112C may also have a tapered shape whose width narrows in an upward direction (i.e., in a direction from the third wiring layer 112C to the second wiring layer 112B).

The electronic device 114 may be positioned on the wiring layer 112B to be electrically connected to the wiring layer 112B. The electronic device 114 may be electrically connected not only to the wiring layer 112B on which the electronic device 114 is disposed, but also to the wiring layer 112 positioned on another layer (e.g., wiring layer 112A). The electronic device 114 may be surface mounted on the wiring layer 112B during a manufacturing process of the support substrate 110, and alignment of the electronic device 114 and the wiring layer 112B may be performed relatively easily. The electronic device 114 may be positioned on a lower side of the wiring layer 112B. That is, a direction from the wiring layer 112B toward the electronic device 114 may be a direction from the second redistribution layer structure 150 to the first redistribution layer structure 140, and accordingly, the wiring layer 112B may be positioned between the electronic device 114 and the second redistribution layer structure 150. In addition, a side of the electronic device 114 facing the wiring layer 112B may face the second redistribution layer structure 150, and a side opposite to the side facing the wiring layer 112B may face the first redistribution layer structure 140. Alternative facing configurations may be implemented without departing from the scope of the disclosure as will be understood by one of skill in the art from the description herein.

In this case, the electronic device 114 may be electrically connected to the second redistribution layer structure 150 through the wiring layer 112B. The electronic device 114 may be positioned to face the second redistribution layer structure 150 with the wiring layer 112B therebetween to be connected to the second redistribution layer structure 150 using a short electrical connection path through the wiring layer 112B. However, the electronic device 114 may be electrically connected to the first redistribution layer structure 140 through the wiring layer 112B, and may also be electrically connected to the semiconductor chip 120 via the first redistribution layer structure 140.

The electronic device 114 may include a pad 114p, and may be connected to the wiring layer 112B through the pad 114p. The pad 114p may face the wiring layer 112B on which the electronic device 114 is positioned. As the electronic device 114 is positioned on a lower side of the wiring layer 112B, the pad 114p may also face the second redistribution layer structure 150. A number of pads 114p is not limited.

The electronic device 114 may be a capacitor such as a multi-layer ceramic capacitor (MLCC) or an integrated stacked capacitor (ISC) having a trench. However, the present disclosure is not limited thereto, and the electronic device 114 may be another type of passive device such as a resistor or inductor, or may be an active device. When the electronic device 114 is an electronic device such as an ISC, the pad 114p may be embedded in a first side of the electronic device 114 or may be positioned on the first side, and the pad 114p may not be positioned on a second side, which is opposite to the first side.

The conductive bump 115 may be positioned between the electronic device 114 and the wiring layer 112B to electrically connect the electronic device 114 and the wiring layer 112B. For example, the conductive bump 115 may electrically connect the electronic device 114 and the wiring layer 112B through the pad 114p of the electronic device 114. The conductive bump 115 may be a micro-bump.

The conductive bump 115 may be made of a conductive material, such as copper (Cu), palladium (Pd), bismuth (Bi), antimony (Sb), tin (Sn), silver (Ag) or an alloy thereof such as a tin-silver (SnAg) alloy.

The underfill 116 may serve to distribute a stress of the conductive bump 115 and to improve connection reliability. However, the support substrate 110 may not include the underfill 116.

The underfill 116 may fill the space between the conductive bump 115 and the electronic device 114, and in some cases, may extend to a side of the electronic device 114 to cover at least a portion of the side of the electronic device 114.

A material of the underfill 116 may be made of an underfill resin such as an epoxy resin, and may include a silica filler flux, etc.

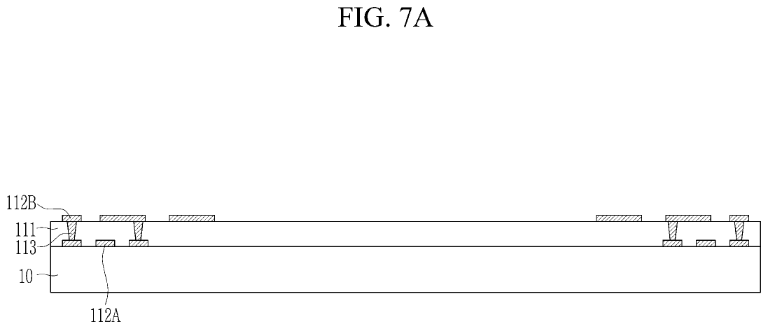

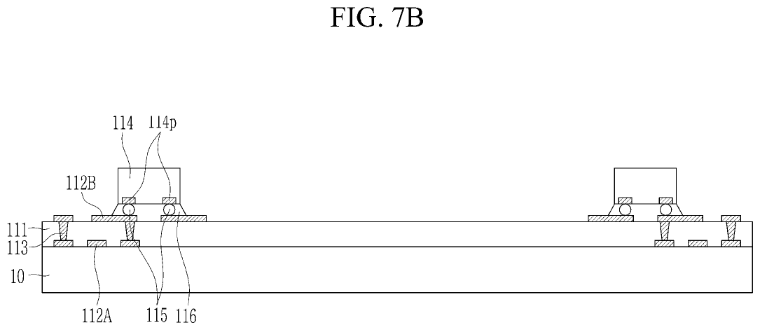

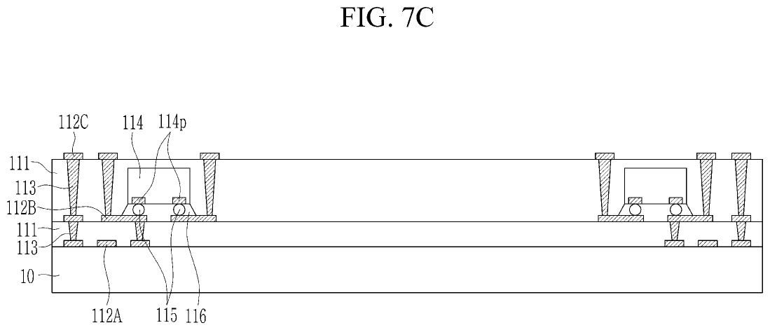

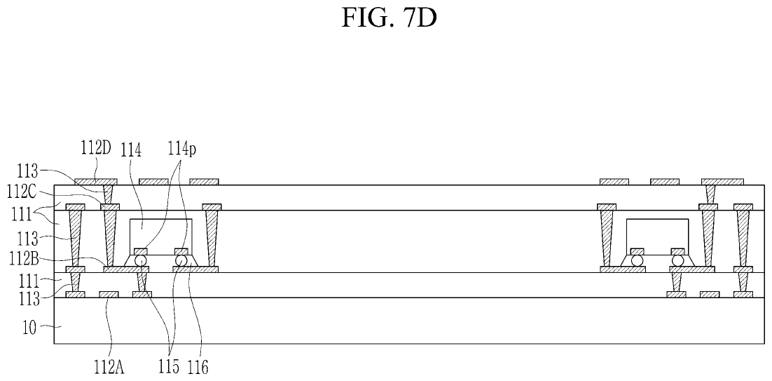

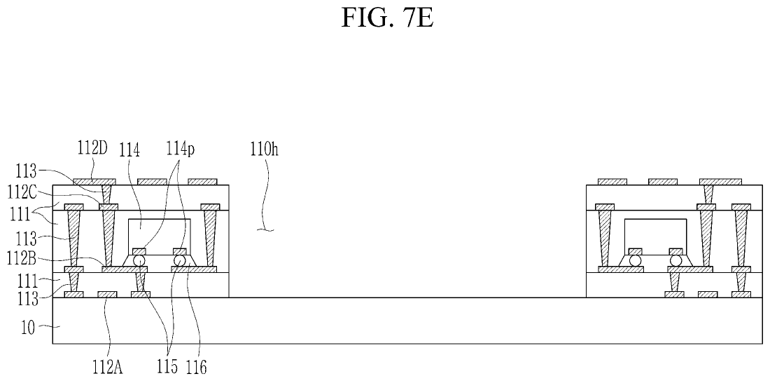

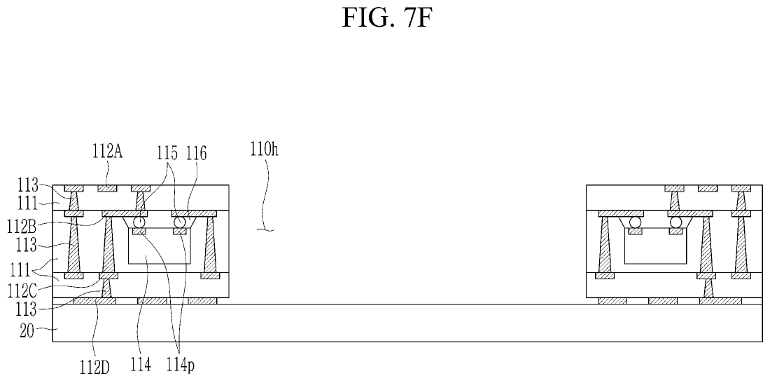

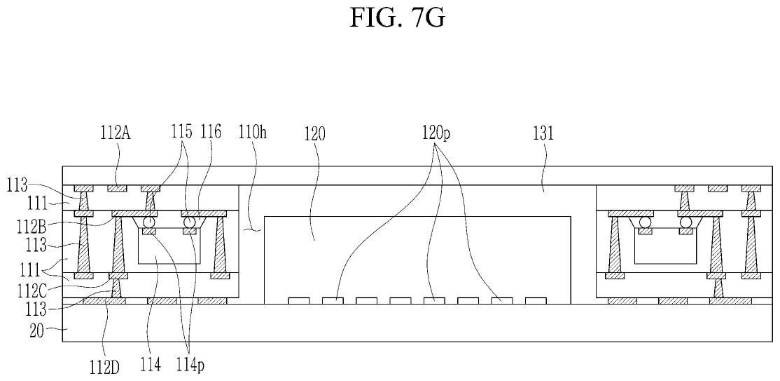

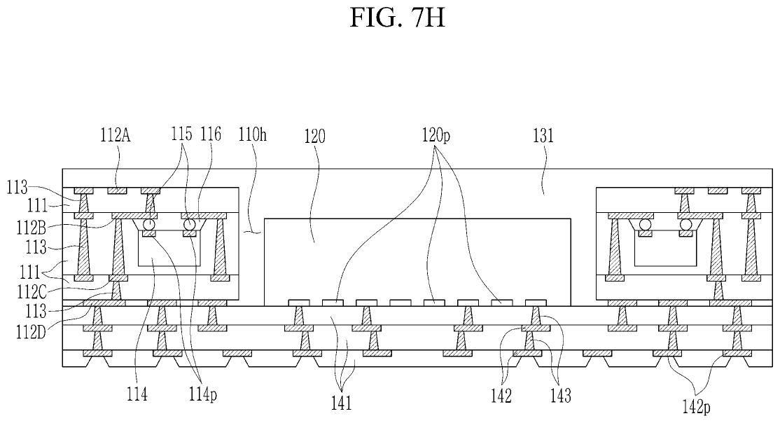

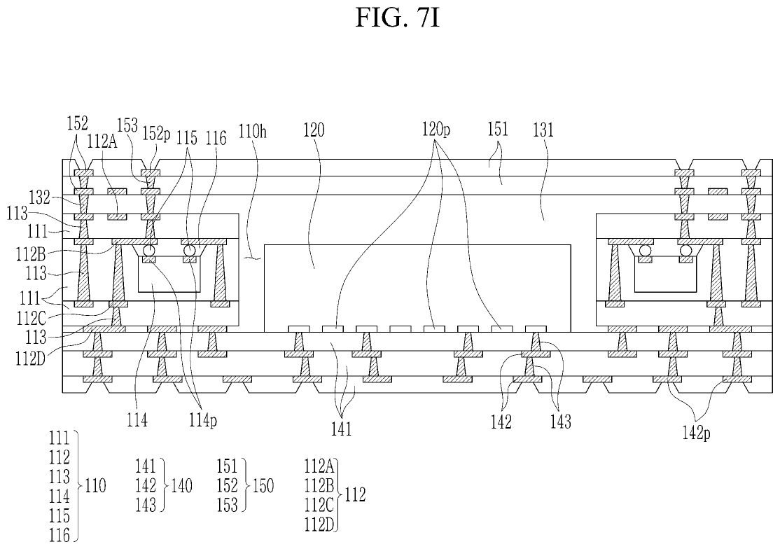

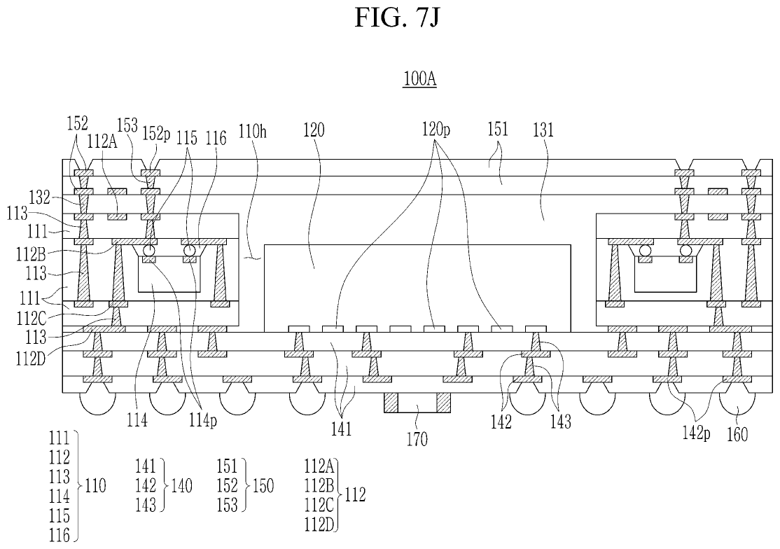

The support substrate 110 may be rotated 180 degrees clockwise. In this case, the wiring layers 112 may be respectively disposed on upper sides of the insulating layers 111 to be covered or at least partially covered by an insulating layer 111 disposed on another layer, and may include exposed portions at a lower side of the insulating layer 111 covering or at least partially covering the wiring layer 112 (e.g., see FIG. 7E). Additionally, the electronic device 114 may be positioned on an upper side of the wiring layer 112B, and the wiring layer 112B may be disposed between the electronic device 114 and the first redistribution layer structure 140.

The semiconductor chip 120 may be positioned in the through hole 110h to be at least partially surrounded by the support substrate 110, and may include a connection pad 120p positioned at a first side.

The connection pad 120p may be at least partially embedded in the semiconductor chip 120, or may be disposed to protrude on a first side of the semiconductor chip 120.

A type of semiconductor chip 120 is not limited. The semiconductor chip 120 may be a logic chip such as a central processing unit (CPU), a graphic processing unit (GPU), or an application processor (AP), or a memory chip such as a dynamic random access memory (DRAM) or a static random access memory (SRAM).

The encapsulant 131 may fill at least a portion of the through hole 110h, and may encapsulate at least a portion of the semiconductor chip 120. In addition, the encapsulant 131 may cover or at least partially cover a side of each of the support substrate 110 and the semiconductor chip 120 facing the second redistribution layer structure 150. The side of each of the support substrate 110 and the semiconductor chip 120 facing the second redistribution layer structure 150 may be exposed at a first side of the encapsulant 131.

An insulating material may be used as a material for the encapsulant 131 (e.g., a thermosetting resin such as an epoxy resin or an epoxy molding compound (EMC)). A process of molding the semiconductor chip 120 with the encapsulant 131 may be performed using compression molding, transfer molding, etc.

One side of the support substrate 110, one side of the semiconductor chip 120, and one side of the encapsulant 131 may be coplanar. As described later, a semiconductor package 100A may be formed in a chip first process that forms the first redistribution layer structure 140 by positioning the support substrate 110 and the semiconductor chip 120 on a carrier film, encapsulating the support substrate 110 and the semiconductor chip 120 with the encapsulant 131, and then removing (e.g., peeling off) the carrier film. Thus, one side of the support substrate 110, one side of the semiconductor chip 120, and one side of the encapsulant 131 may have a coplanar structure.

The semiconductor package 100A may further include a via 132 that penetrates through the encapsulant 131 and connects a second redistribution layer 152 and one of the wiring layers 112.

A material of the via 132 may include aluminum (Al), copper (Cu), gold (Au), silver (Ag), platinum (Pt), tin (Sn), chromium (Cr), palladium (Pd), lead (Pb), titanium (Ti), or an alloy thereof.

The via 132 may be formed by forming a via hole in the encapsulant 131 using methods such as laser drilling or photo lithography, disposing a seed layer on a sidewall of the via hole by electroless plating, and filling the via hole with electrolytic plating, but the present disclosure is not limited thereto. The via 132 may be formed integrally with the second redistribution layer 152 positioned on a lowermost side of the second redistribution layer 152 such that there is no boundary therebetween. When forming the seed layer on the sidewall of the via hole, the via 113 and the second redistribution layer 152 may be integrally formed by extending the seed layer on a first side of the encapsulant 131 and performing electrolytic plating.

The via 132 may have a tapered shape with a width that narrows in the direction from the second redistribution layer 152 to the wiring layer 112, but the present disclosure is not limited thereto, and the via 132 may have a cylindrical shape, for example.

The first redistribution layer structure 140 may be disposed on a first side of the semiconductor chip 120 where the connection pad 120p is positioned, and may include an insulating layer 141 (e.g., a plurality of insulating layers 141), a first redistribution layer 142 (e.g., a plurality of first redistribution layers 142), and a via 143 (e.g., a plurality of vias 143).

The insulating layer 141 may include an insulating material, such as a photo-imageable dielectric (PID) element. The PID element may include a polyimide-based photosensitive polymer, a novolak-based photosensitive polymer, polybenzoxazole, a silicone-based polymer acrylate-based polymer, or an epoxy-based polymer. Alternatively, an inorganic dielectric material such as a silicon nitride or a silicon oxide may be used as a material for the insulating layer 141.

The insulating layer 141 may include a plurality of insulating layers 141. A number of the insulating layers 141 is not particularly limited, and may be changed according to a design thereof. Materials of the insulating layers 141 may be the same or different from each other. When the materials of the insulating layers 141 are the same, a boundary between the insulating layers 141 may not be clear. A thickness of the insulating layer 141 may be substantially the same as or vary with respect to a thickness of the insulating layer 111 of the support substrate 110.

The first redistribution layer 142 may be electrically connected to the semiconductor chip 120 and the wiring layer 112.

The first redistribution layer 142 may include a plurality of first redistribution layers 142. A number of the first redistribution layers 142 is also not limited, and may be changed according to a design thereof. The first redistribution layers 142 may be disposed on the respective insulating layers 141 to be covered or at least partially covered by the insulating layer 141 disposed in another layer.

The first redistribution layer 142 may include a connection pad 142p that is physically and electrically connected to the connection structure 160. The connection pad 142p may be included in a lowermost first redistribution layer 142 among the first redistribution layers 142. The insulating layer 141 may have an opening exposing the connection pad 142p. The insulating layer 141 having an opening exposing the connection pad 142p may be the insulating layer 141 disposed at a lowermost side among the insulating layers 141.

The first redistribution layer 142 may include a conductive material such as aluminum (Al), copper (Cu), gold (Au), silver (Ag), platinum (Pt), tin (Sn), chromium (Cr), palladium (Pd), lead (Pb), titanium (Ti), or an alloy thereof.

The first redistribution layer 142 may be formed by forming a seed layer through electroless plating, and forming a metal layer on the seed layer through electrolytic plating, but the present disclosure is not limited thereto.

The via 143 may extend through the insulating layer 141, and may be configured to connect the wiring layer 112 to the first redistribution layer 142 or to connect the first redistribution layers 142 positioned in different layers to each other.

A material of the via 143 may be the same as the forming material of the first redistribution layer 142, such as aluminum (Al), copper (Cu), gold (Au), silver (Ag), platinum (Pt), tin (Sn), chromium (Cr), palladium (Pd), lead (Pb), titanium (Ti), or an alloy thereof.

The via 143 may be formed by forming a via hole in the insulating layer 141 using methods such as laser drilling or photo lithography, disposing a seed layer on a sidewall of the via hole by electroless plating, and filling the via hole with electrolytic plating, but the present disclosure is not limited thereto. The via 143 may be formed integrally with the first redistribution layer 142 such that there is no boundary therebetween. When forming the seed layer on the sidewall of the via hole, the via 143 and the first redistribution layer 142 may be integrally formed by extending the seed layer on a first side of the insulating layer 141 and performing electrolytic plating.

The via 143 may have various shapes, such as a tapered shape in which a diameter thereof narrows in a direction from a first side to a second side, or a cylindrical shape, according to a formation method.

The second redistribution layer structure 150 may be disposed on a second side of the semiconductor chip 120, which is opposite to a first side of the semiconductor chip 120, and may include an insulating layer 151, a redistribution layer 152, and a via 153. That is, the second redistribution layer structure 150 may be disposed above the semiconductor chip 120 and on the encapsulant 131, such that the second redistribution layer structure 150 is over the semiconductor chip 120.

The insulating layer 151 may include a material such as a PID element may be used. The PID element may include a polyimide-based photosensitive polymer, a novolak-based photosensitive polymer, polybenzoxazole, a silicone-based polymer acrylate-based polymer, or an epoxy-based polymer. Alternatively, an inorganic dielectric material such as a silicon nitride or a silicon oxide may be used as a material for the insulating layer 151.

The insulating layer 151 may include a plurality of insulating layers 151. A number of the insulating layers 151 is not particularly limited, and may be changed according to a design thereof. Materials of the insulating layers 151 may be the same or different from each other. When the materials of the insulating layers 151 are the same, a boundary between the insulating layers 151 may not be clear. A thickness of the insulating layer 151 may be substantially the same as or vary with respect to a thickness of the insulating layer 111. In addition, the thickness of the insulating layer 151 may be substantially the same as or vary with respect to a thickness of the insulating layer 111.

The second redistribution layer 152 may be electrically connected to the wiring layer 112.

The second redistribution layer 152 may include a plurality of second redistribution layers 152. A number of the second redistribution layers 152 is also not particularly limited, and may be changed according to a design thereof. The second redistribution layers 152 may be disposed on the respective insulating layers 151 to be covered or at least partially covered by the insulating layer 151 disposed in another layer. However, the lowermost second redistribution layer 152 among the second redistribution layers 152 may be disposed on the encapsulant 131 to be covered or at least partially covered by the insulating layer 151.

The second redistribution layer 152 may include a connection pad 152p for physical and electrical connection with another component, such as another semiconductor package. The connection pad 152p may be included in the uppermost second redistribution layer 152 among the second redistribution layers 152. The insulating layer 151 may have an opening exposing the connection pad 152p. The insulating layer 151 having an opening exposing the connection pad 152p may be the uppermost insulating layer 151 among the insulating layers 151.

The second redistribution layer 152 may include a conductive material, such as aluminum (Al), copper (Cu), gold (Au), silver (Ag), platinum (Pt), tin (Sn), chromium (Cr), palladium (Pd), lead (Pb), titanium (Ti), or an alloy thereof.

The second redistribution layer 152 may be formed by forming a seed layer through electroless plating, and forming a metal layer on the seed layer through electrolytic plating, but the present disclosure is not limited thereto.

The via 153 may extend through the insulating layer 151, and may be configured to connect the second redistribution layers 152 disposed in different layers.

The material of the via 153 may be the same as the forming material of the second redistribution layer 152, such as aluminum (Al), copper (Cu), gold (Au), silver (Ag), platinum (Pt), tin (Sn), chromium (Cr), palladium (Pd), lead (Pb), titanium (Ti), or an alloy thereof.

The via 153 may be formed by forming a via hole in the insulating layer 151 using methods such as laser drilling or photo lithography, disposing a seed layer on a sidewall of the via hole by electroless plating, and filling the via hole with electrolytic plating, but the present disclosure is not limited thereto. The via 153 may be formed integrally with the second redistribution layer 152 such that there is no boundary therebetween. When forming the seed layer on the sidewall of the via hole, the via 153 and the second redistribution layer 152 may be integrally formed by extending the seed layer on a first side of the insulating layer 151 and performing electrolytic plating.

The via 153 may have various shapes, such as a tapered shape in which a diameter thereof narrows in a direction from a first side to a second side, or a cylindrical shape according to a formation method.

The connection structure 160 may be positioned on a side opposite to a side facing the semiconductor chip 120 of the first redistribution layer structure 140, and may physically and electrically connect the semiconductor package 100A to another component such as a printed circuit board. The connection structure 160 may be positioned on the connection pad 142p of the first redistribution layer structure 140, may fill the opening of the insulating layer 141, and may extend onto the insulating layer 141.

The connection structure 160 may include a conductive material, and it may be formed of, e.g., solder. A size, a number, an interval, etc. of the connection structure 160 are not particularly limited.

The semiconductor package 100A may further include an electronic device 170 positioned on a side of the first redistribution layer structure 140 opposite to a side facing the semiconductor chip 120. The electronic device 170 may be positioned between the connection structures 160 on the first redistribution layer structure 140.

The electronic device 170 may be electrically connected to the first redistribution layer 142 and the semiconductor chip 120. Additionally, the electronic device 170 may be electrically connected to the wiring layer 112 and the second redistribution layer 152 as needed.

The electronic device 170 may be relatively thin. For example, the thickness of the electronic device 170 may be smaller than the thickness of the electronic device 114. Additionally, the electronic device 170 may be positioned at a higher level than that the connection structure 160 for connection between the semiconductor package 100A and another component.

The electronic device 170 may be a passive device such as a resistor, an inductor, or a capacitor such as an ISC, a MLCC, or a land side capacitor.

In a ball grid array (BGA) package structure, an electronic device may be mounted on a lower side of the package with solder balls using surface mount technology (SMT). In this case, a number of electronic devices that can be mounted on the semiconductor package may be limited due to an area, a number, etc. occupied by the balls.

In addition, in a package on package (POP) structure in which other semiconductor packages are stacked on a semiconductor package, there are cases where an electronic device electrically connected to the semiconductor chip of the upper package is needed. In this case, the electronic device may be positioned such that the electronic device has a short electrical connection path with the semiconductor chip of the upper package.

In the semiconductor package 100A according to an embodiment, the electronic device 114 may be placed on the support substrate 110, and thus a number of electronic devices 170 mounted together with the connection structure 160 on the first redistribution layer structure 140 may be minimized. Disposition of the electronic devices 170 on the first redistribution layer structure 140 may not be necessary. In addition, the electronic device 114 may be placed in the dummy area of the semiconductor package 100A, and a size of the semiconductor package is not affected. Accordingly, according to some embodiments, a semiconductor package may be provided that overcomes space constraints for disposition of electronic devices without increasing the size of the semiconductor package.

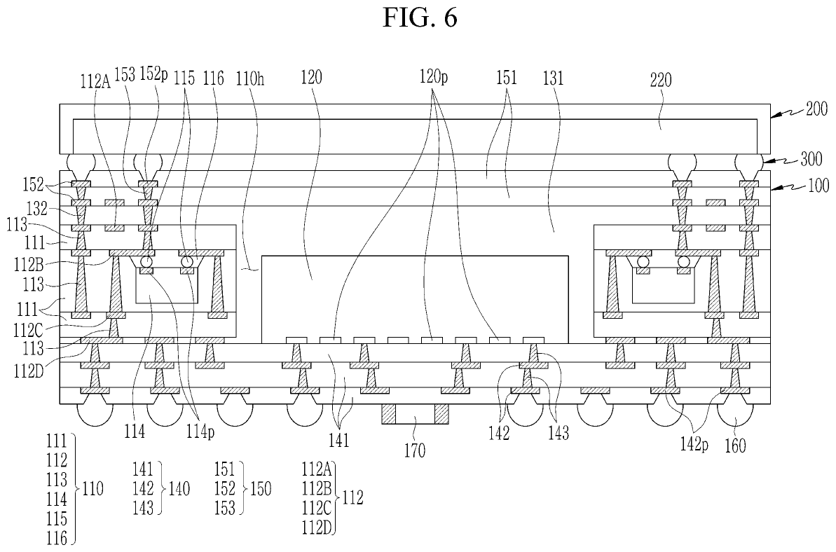

Additionally, the electronic device 114 may be electrically connected to the second redistribution layer structure 150, and may be connected to a second semiconductor package 200 (see FIG. 6) positioned on the semiconductor package 100A. Accordingly, performance such as a power characteristic of the second semiconductor package 200 may be improved. Particularly, if the number of electronic devices that can be mounted on a lower surface of the second semiconductor package 200 is limited due to an area, a number, etc. occupied by a connection structure 300 on the lower surface of the second semiconductor package 200, performance may be improved by positioning the electronic device 114 on the support substrate 110 of the first semiconductor package 100 and connecting the electronic device 114 to the second semiconductor package 200. The electronic device 114 may be positioned to face the second redistribution layer structure 150 to have a short electrical connection path with the second semiconductor package 200.

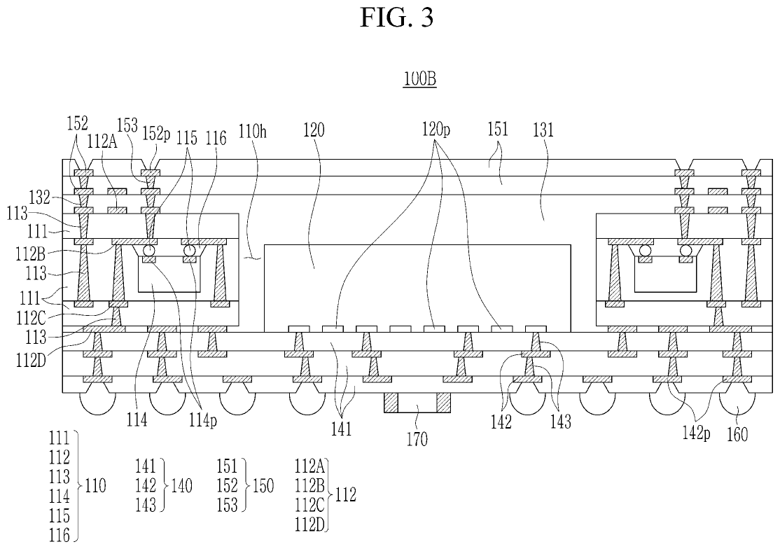

FIG. 3 is a cross-sectional view illustrating a semiconductor package according to one or more example embodiments. FIG. 3 may include features similar to those described above, and repeated descriptions may be omitted.

Referring to FIG. 3, a semiconductor package 100B according to an embodiment may have a structure of the support substrate 110 that is different from that of the semiconductor package 100A.

Specifically, the uppermost wiring layer 112A among the wiring layers 112 of the support substrate 110 may be disposed on the uppermost insulating layer 111 among the insulating layers 111. Accordingly, the wiring layer 112A may be disposed on opposite surfaces of the uppermost insulating layer 111. In addition, the via 113 penetrating through the insulating layer 111 disposed at an uppermost side may have a tapered shape with a width that narrows downward.

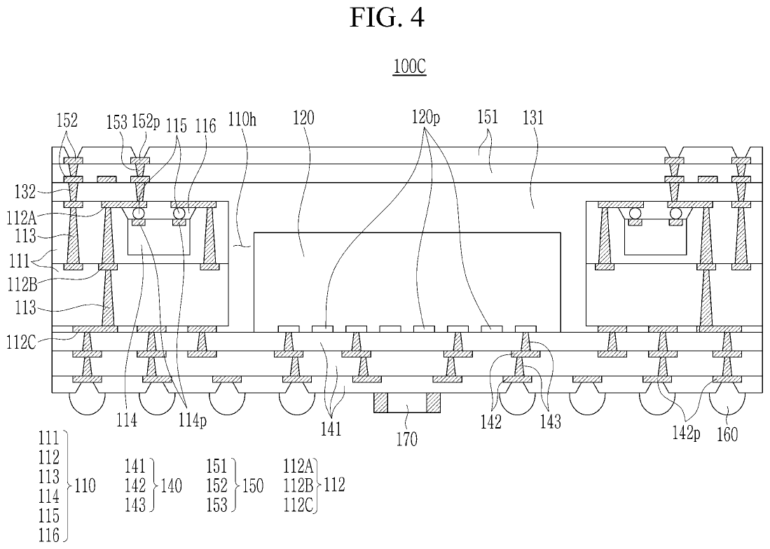

FIG. 4 is a cross-sectional view illustrating a semiconductor package according to one or more example embodiments. FIG. 4 may include features similar to those described above, and repeated descriptions may be omitted.

Referring to FIG. 4, in a semiconductor package 100C according to an embodiment, the electronic device 114 may be positioned on the wiring layer 112A disposed at an uppermost side among the wiring layers 112. The wiring layer 112A therefore is the wiring layer closest to the second redistribution structure 150 among the wiring layers 112. The height of the insulating layer 111 that is below the electronic device 114 is increased, and the via 113 in this insulating layer 111 is also increased in height, as compared to FIG. 1. As compared to FIG. 1, the insulating layer 111 above the electronic device 114 is removed. When the electronic device 114 is positioned on the wiring layer 112A disposed at an uppermost side, an electrical connection path between the electronic device 114 and the second redistribution layer structure 150 may be minimized. Accordingly, an electrical connection path between the electronic device 114 and the second semiconductor package 200, which will be described later, may also be minimized, and performance of the second semiconductor package 200 may be improved more efficiently.

The insulating layer 111 is illustrated as having two insulating layers 111, and the support substrate 110 may include fewer or more insulating layers 111. For example, the insulating layer 111 may be one insulating layer 111, or it may be three, four or more insulating layers 111.

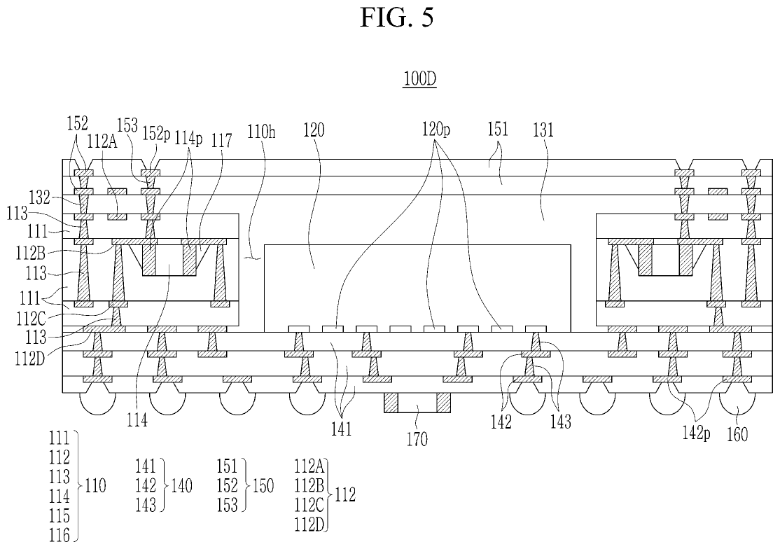

FIG. 5 is a cross-sectional view illustrating a semiconductor package according to one or more example embodiments. FIG. 5 may include features similar to those described above, and repeated descriptions may be omitted.

Referring to FIG. 5, a semiconductor package 100D according to an embodiment is different from the semiconductor package 100A in the mounting method of the electronic device 114.

The electronic device 114 may be positioned on the wiring layer 112B by a conductive member 117. The conductive member 117 may cover or at least partially cover a side surface of the electronic device 114, and May further cover or at least partially cover a surface of the electronic device 114 facing the wiring layer 112B. A material of the conductive member 117 may be solder paste.

FIG. 6 is a cross-sectional view illustrating a semiconductor package having a structure in which other semiconductor packages are stacked thereon, according to one or more example embodiments. FIG. 6 may include features similar to those described above, and repeated descriptions may be omitted.

Referring to FIG. 6, the semiconductor package may include a first semiconductor package 100 and a second semiconductor package 200 disposed on the first semiconductor package 100. The first semiconductor package 100 and the second semiconductor package 200 may be connected to each other using the connection structure 300.

The first semiconductor package 100 may be one of the semiconductor packages 100A to 100D described above.

The second semiconductor package 200 may be disposed on the second redistribution layer structure 150, and may be electrically connected to the first semiconductor package 100.

The second semiconductor package 200 may have various structures. The second semiconductor package 200 may include a substrate, a second semiconductor chip 220 positioned on the substrate, and an encapsulant for encapsulating the second semiconductor chip 220.

The second semiconductor chip 220 may be electrically connected to the electronic device 114 of the first semiconductor package 100. Accordingly, performance such as a power characteristic of the second semiconductor package 200 may be improved. Particularly, if the number of electronic devices that can be mounted on a lower surface of the second semiconductor package 200 is limited due to an area, a number, etc. occupied by the connection structure 300 on the lower surface of the second semiconductor package 200, performance may be improved by positioning the electronic device 114 on the support substrate 110 of the first semiconductor package 100 and connecting it to the second semiconductor package 200. The electronic device 114 may be positioned to face the second redistribution layer structure 150 to have a short electrical connection path with the second semiconductor package 200.

FIGS. 7A to 7J are diagrams illustrating a manufacturing process of a semiconductor package according to one or more example embodiments.

Referring to FIGS. 7A to 7J, a manufacturing method for a semiconductor package may include preparing the support substrate 110, forming the through hole 110h in the support substrate 110, positioning the semiconductor chip 120 in the through hole 110h, encapsulating the semiconductor chip 120, forming the first redistribution layer structure 140 including the first redistribution layer 142 on a first surface of the semiconductor chip 120, and forming a second redistribution layer structure 150 including the second redistribution layer 152 on a second surface of the semiconductor chip 120, which is opposite to the first surface of the semiconductor chip 120. The manufacturing method for a semiconductor package may further include positioning the connection structure 160 and the electronic device 170 on the first redistribution layer structure 140.

Referring to FIG. 7A to FIG. 7D, the support substrate 110 may be prepared on a first carrier film 10. The first carrier film 10 may be a film used in a semiconductor package manufacturing process, such as a die attach film (DAF).

The preparing of the support substrate 110 may be performed by repeating forming the insulating layer 111, forming the via 113 penetrating through the insulating layer 111, and forming the wiring layer 112 on the insulating layer 111. In this case, the lowermost wiring layer 112 may be disposed on the first carrier film 10, and the lowermost insulating layer 111 may be formed to cover or at least partially cover the lowermost wiring layer 112.

The preparing the support substrate 110 according to some embodiments may further include positioning the electronic device 114 on one wiring layer 112 among the wiring layers 112. Accordingly, the insulating layer 111 covering or at least partially covering the wiring layer 112 on which the electronic device 114 is disposed may be formed to cover or at least partially cover the electronic device 114 together with the wiring layer 112. Among the wiring layers 112, the wiring layer 112 where the electronic devices 114 are positioned may be changed according to a design thereof. As such, the electronic device 114 may be surface mounted on the wiring layer 112 during a manufacturing process of the support substrate 110, and alignment of the electronic device 114 and the wiring layer 112 may be easily performed.

Referring to FIG. 7E, the through hole 110h may be formed in the support substrate 110. The forming of the through hole 110h in the support substrate 110 may be performed on the first carrier film 10, or on a second carrier film 20. That is, the support substrate 110 having no through hole 110h may be positioned on the second carrier film 20, and after removing (e.g., peeling off) the first carrier film 10, the through hole 110h may be formed.

In the forming the through hole 110h in the support substrate 110, the through hole 110h may be formed to extend through the support substrate 110 in a thickness direction from a first surface of the support substrate 110 to a second surface. A method of forming the through hole 110h is not particularly limited, and may be formed, for example, by laser drilling, mechanical drilling, sand blasting, etc. According to a method of forming the through hole 110h, a width of the through hole 110h may be substantially constant in the direction from the first side of the support substrate 110 to the second side, or may be narrowed.

Referring to FIG. 7F, the support substrate 110 may be positioned on the second carrier film 20, and the first carrier film 10 is removed (e.g., peeled off). That is, the device may be flipped (i.e., rotated 180 degrees). The second carrier film 20 may also be a film commonly used in the semiconductor package manufacturing process, such as a DAF, and the support substrate 110 and the semiconductor chip 120 may be fixed. The first carrier film 10 may be separated from the support substrate 110 by applying heat, but the present disclosure is not limited thereto.

Referring to FIG. 7G, the semiconductor chip 120 may be positioned in the through hole 110h and encapsulated with an encapsulant 131. The positioning of the semiconductor chip 120 in the through hole 110h may be performed on the second carrier film 20. In this case, the semiconductor chip 120 may be positioned directly on the second carrier film 20 to contact the second carrier film 20. Accordingly, in the final semiconductor package structure, a first surface of the support substrate 110 and a first surface of the semiconductor chip 120 may be coplanar.

The encapsulating of the semiconductor chip 120 may be performed by compression molding, transfer molding, etc., and a material of the encapsulant 131 may include a thermosetting resin such as an epoxy resin, an EMC, etc. The encapsulating of the semiconductor chip 120 may also be performed on the second carrier film 20. Accordingly, in the final semiconductor package structure, a first surface of the encapsulant 131 may be coplanar with a first surface of the support substrate 110 and a first surface of the semiconductor chip 120.

Referring to FIG. 7H, the second carrier film 20 may be removed (e.g., peeled off), and the first redistribution layer structure 140 may be formed.

The second carrier film 20 may also be separated from the support substrate 110 by applying heat, but the present disclosure is not limited thereto.

The first redistribution layer structure 140 may be formed by repeating the forming the insulating layer 141, forming the via 143 penetrating through the insulating layer 141, and forming the first redistribution layer 142 on the insulating layer 141. In addition, an opening may be formed in the lowermost insulating layer 141 to expose the connection pad 142p.

Referring to FIG. 7I, the second redistribution layer structure 150 may be formed.

The second redistribution layer structure 150 may be formed by repeating the forming the insulating layer 151, forming the via 153 penetrating through the insulating layer 151, and forming the second redistribution layer 152 on the insulating layer 151. However, the lowermost second redistribution layer 152 may be disposed on the encapsulant 131. In addition, an opening may be formed in the uppermost insulating layer 151 to expose the connection pad 152p.

Referring to FIG. 7J, the connection structure 160 and the electronic device 170 may be positioned on the first redistribution layer structure 140. The connection structure 160 may be positioned on the connection pad 142p of the first redistribution layer structure 140. Additionally, the connection structure 160 may fill an opening of the insulating layer 141, and may extend onto the insulating layer 141.

The electronic device 170 may be positioned on the first redistribution layer structure 140 to be electrically connected to the first redistribution layer 142 and the semiconductor chip 120. Additionally, the electronic device 170 may be electrically connected to the wiring layer 112 and the second redistribution layer 152 as needed.

The description of each component included in the semiconductor package according to some embodiments may be equally applied to the description of each component included in the semiconductor package manufacturing method according to some embodiments.

According to an aspect of the present disclosure, a semiconductor package capable of overcoming limitations of space constraints for disposition of electronic devices may be provided.

According to another aspect of the present disclosure, a semiconductor package having a short electrical connection path with a semiconductor chip may be provided.

According to another aspect of the present disclosure, a semiconductor package with improved performance may be provided.

Each of the embodiments provided in the above description is not excluded from being associated with one or more features of another example or another embodiment also provided herein or not provided herein but consistent with the disclosure.

While certain embodiments of the disclosure has been particularly shown and described, it will be understood that various changes in form and details may be made therein without departing from the spirit and scope of the following claims.

What is claimed is:

1. A semiconductor package comprising:
a support substrate having a through hole extending from a first side of the support substrate to a second side of the support substrate opposite to the first side of the support substrate and comprising:
an insulating layer;
one or more wiring layers comprising a first wiring layer; and
a first electronic device on the first wiring layer;
a semiconductor chip positioned in the through hole to be at least partially surrounded by the support substrate and comprising a connection pad on a first surface of the semiconductor chip;
an encapsulant filling at least a portion of the through hole and encapsulating at least a portion of the semiconductor chip;
a first redistribution layer structure on the first surface of the semiconductor chip and comprising a first redistribution layer; and
a second redistribution layer structure over a second surface of the semiconductor chip that is opposite to the first surface of the semiconductor chip, the second redistribution layer structure comprising a second redistribution layer,
wherein the first wiring layer is between the first electronic device and the second redistribution layer structure, and
wherein the insulating layer integrally covers the first wiring layer, a side surface of the first electronic device, and a surface of the first electronic device opposite to a surface of the first electronic device facing the first wiring layer.

2. The semiconductor package of claim 1, wherein the first electronic device is electrically connected to the second redistribution layer structure.

3. The semiconductor package of claim 1, wherein the first electronic device comprises a pad facing the first wiring layer.

4. The semiconductor package of claim 3, wherein the support substrate further comprises a conductive bump between the first electronic device and the first wiring layer, and connecting the first electronic device and the first wiring layer through the pad.

5. The semiconductor package of claim 1, wherein the one or more wiring layers further comprises a second wiring layer, and wherein the first wiring layer is the wiring layer closest to the second redistribution structure among the wiring layers.

6. The semiconductor package of claim 1, wherein the one or more wiring layers further comprises a second wiring layer on the insulating layer, and
wherein the support substrate further comprises a via penetrating the insulating layer and connecting the first wiring layer and the second wiring layer.

7. The semiconductor package of claim 6, wherein the via has a tapered shape with a width that narrows in a direction from the second wiring layer to the first wiring layer.

8. The semiconductor package of claim 1, further comprising a via penetrating the encapsulant and to connecting the second redistribution layer to one of the one or more wiring layers.

9. The semiconductor package of claim 1, wherein the first electronic device is a capacitor.

10. The semiconductor package of claim 1, wherein one surface of the support substrate, one surface of the semiconductor chip, and one surface of the encapsulant are substantially coplanar.

11. The semiconductor package of claim 1, wherein the first wiring layer is exposed at one surface of the insulating layer.

12. The semiconductor package of claim 1, further comprising a second electronic device on a first surface of the first redistribution layer structure opposite to a second surface of the first redistribution layer structure facing the semiconductor chip.

13. The semiconductor package of claim 1, further comprising a connection structure on a first surface of the first redistribution layer structure opposite to a second surface of the first redistribution layer structure facing the semiconductor chip.

14. A semiconductor package comprising:
a first semiconductor package; and
a second semiconductor package on the first semiconductor package,
wherein the first semiconductor package comprises:
a support substrate comprising:
one or more wiring layers comprising a first wiring layer;
a first electronic device on the first wiring layer; and
an insulating layer at least partially covering the first wiring layer and the first electronic device;
a first semiconductor chip;
an encapsulant encapsulating at least a portion of the first semiconductor chip;
a first redistribution layer structure comprising a first redistribution layer on a first surface of the first semiconductor chip, the first redistribution layer being connected to the first semiconductor chip and the one or more wiring layers; and
a second redistribution layer structure comprising a second redistribution layer over a second surface of the first semiconductor chip opposite to the first surface of the first semiconductor chip, the second redistribution layer being connected to the one or more wiring layers, and
wherein the second semiconductor package comprises a second semiconductor chip electrically connected to the first electronic device.

15. The semiconductor package of claim 14, wherein the second semiconductor package is on the second redistribution layer structure, and
wherein the first wiring layer is between the first electronic device and the second redistribution layer structure.

16. The semiconductor package of claim 14, wherein the one or more wiring layers further comprises a second wiring layer, and wherein the first wiring layer is the wiring layer closest to the second redistribution structure among the wiring layers.

17. The semiconductor package of claim 14, further comprising a second electronic device on a first surface of the first redistribution layer structure opposite to a second surface of the first redistribution layer structure facing the first semiconductor chip,
wherein the second electronic device is connected to the first semiconductor chip.

18. A method of manufacturing a semiconductor package, comprising:
preparing a support substrate;
forming a through hole in the support substrate;
providing a semiconductor chip in the through hole;
encapsulating the semiconductor chip;
forming a first redistribution layer structure on a first surface of the semiconductor chip, the first redistribution layer structure comprising a first redistribution layer; and
forming a second redistribution layer structure over a second surface of the semiconductor chip opposite to the first surface of the semiconductor chip, the second redistribution layer structure comprising a second redistribution layer,
wherein the preparing the support substrate comprises:
forming a wiring layer;
providing an electronic device on the wiring layer; and
forming an insulating layer to at least partially cover the wiring layer and the electronic device.

19. The method of claim 18, wherein the support substrate is prepared on a first carrier film,
wherein the method further comprises:
positioning the support substrate on a second carrier film;
removing the first carrier film; and
removing the second carrier film,
wherein the providing of the semiconductor chip in the through hole is performed on the second carrier film.

20. The method of claim 19, wherein the semiconductor chip is provided directly on the second carrier film.
